(19) United States
(12) Patent Application Publication
(10) Pub. No.: US 2005/0032500 A1
(43) Pub. Date: Feb. 10, 2005

(54) Wireless/IR headphones with integrated rear seat audio control for automotive entertainment system

(75) Inventors: Peter J. Nashif, Belleville, MI (US); Sorin Panainte, Southgate, MI (US)

Correspondence Address: VISTEON, C/O BRINKS HOFER GILSON & LIONE, PO BOX 10395, CHICAGO, IL, 60610, US

(73) Assignee: Visteon Global Technologies, Inc.

(21) Appl. No.: 10/637,211

(22) Filed: Aug. 8, 2003

(51) Int. Cl. H05K 11/00

(52) U.S. Cl. 455/345; 455/344; 455/346

(57) ABSTRACT

The present invention provides an automotive multimedia entertainment system having an audio system connected to multiple audio input sources and a headphone. The audio system includes front and rear channels that can be configured independently. The headphone is connected to the audio system over a two-way wireless communication link. A set of controls are integrated into the headphone for configuring the audio system across the two-way wireless communication link. The audio system also provides for two modes of operation. In the first mode, both the front and rear speakers generate an audio output according to the first channel. In the second mode the front speakers provide an audio output according to the first channel, the rear speakers are deactivated, and an audio signal is transmitted to the headphones from the second channel of the audio system. In another aspect of the invention, the wireless headphone includes controls mounted on the headphone and which generate control signals across the two-way communication link that adjust the configuration of the radio.

### BACKGROUND

1. Field of the Invention

The present invention generally relates to an automotive multimedia entertainment system. More specifically, the invention relates to a wireless IR headphone integrated to an automotive multimedia entertainment system.

2. Description of Related Art

Many automotive multimedia entertainment systems include a rear seat entertainment module. The rear seat entertainment module allows rear seat passengers to control and select audio sources from the rear seat. It is desirable for each rear seat passenger to have convenient access to the controls of the rear seat entertainment module. Ideally, each rear seat passenger would have their own conveniently located rear seat entertainment control.

Currently, the manufacture of rear seat entertainment controls is very complex and costly. The number of control modules required for each model car and color interior in conjunction with the increasing number of audio sources increase the cost of the controls and generate significant complexity for the rear seat module supplier. In addition, the increased number of controls in the rear seat module has increased the cost and complexity of the car wire harness.

Although some manufactures have tried to consolidate the number of controls by providing a single overhead unit for all rear seat passengers to control the rear seat entertainment module. These units are not convenient for the rear seat passenger and often require the passenger to leave the belted position to reach the controls.

Further, some automotive multimedia entertainment systems allow the front passenger to listen to a different audio source than the rear passenger. However, when playing simultaneously the rear audio device can be heard by the front passenger and the front audio device can be heard by the rear passenger. Hearing both audio devices is distracting to most passengers and detracts from the value of the rear entertainment module.

In view of the above, it is apparent that there exists a need for an improved automotive multimedia entertainment system providing better manufacturability, reduced complexity, and improved passenger convenience.

### SUMMARY

In satisfying the above need, as well as overcoming the enumerated drawbacks and other limitations of the related art. The present invention provides for an automotive multimedia entertainment system having an audio system connected to multiple audio input sources, speakers and a headphone.

The audio system includes a front channel and back channel which can be configured independently. The headphone is connected to the audio system across a two-way wireless communication link. The headphone has an integrated set of controls for configuring the audio system. The audio system provides for a dual play feature including two modes. In the first mode, both the front and rear speakers generate an audio output according to the first channel. In the second mode the front speakers provide an audio output according to the first channel, the rear speakers are deactivated, and an audio signal is transmitted to the headphones from the second channel of the audio system.

In another aspect of the invention, the wireless headphone includes controls mounted on the headphone for generating control signals across the two-way communication link for adjusting the configuration of the radio.

In another aspect of the invention, multiple headphones are provided utilizing the same set of command signals across the two-way communication link resulting in the headphones being completely interchangeable without reconfiguration of the headphones.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 is a diagrammatic view of an automotive multimedia entertainment system according to the present invention;

FIG. 2 is a flowchart showing a method for controlling the automotive, entertainment system according to multimedia the present invention;

### DETAILED DESCRIPTION

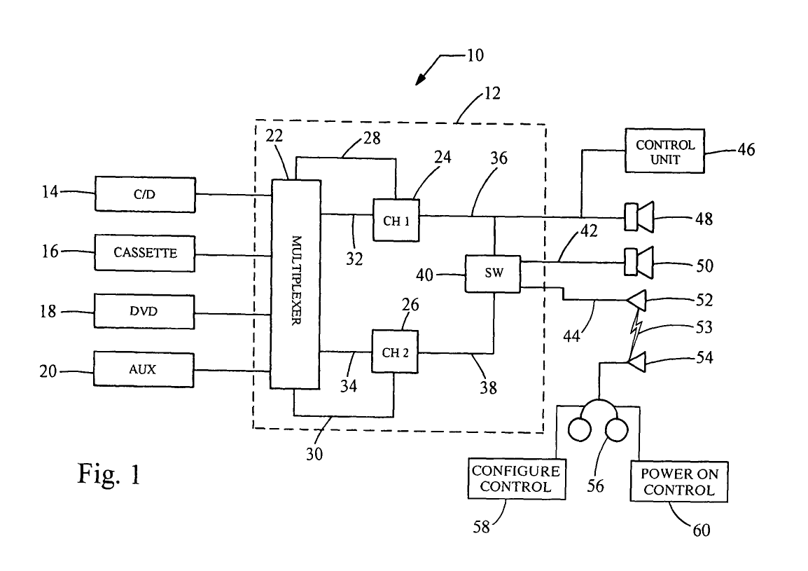

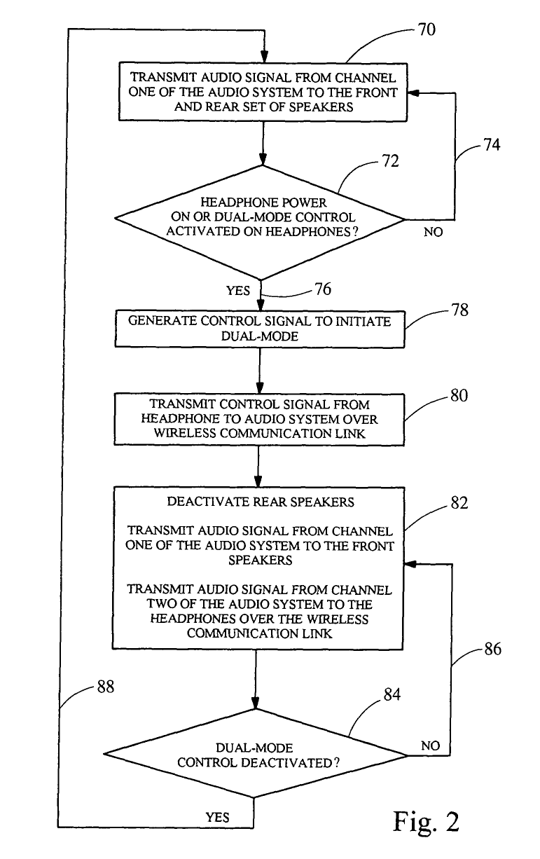

Referring now to FIGS. 1 and 2, an automotive multimedia entertainment system embodying the principles of the present invention is illustrated therein and designated at 10. As its primary components, the automotive multimedia entertainment system 10 includes an audio system 12, a headphone 56, a two way wireless communication link 53, a set of front speakers 48, and a set of rear speakers 50.

The audio system 12 can receive audio input signals from multiple audio input devices, for example a CD player 14, a cassette player 16, a DVD player 18, and other auxiliary devices 20. The audio input signals are received by the multiplexer 22 of the audio system 12. The multiplexer 22 can provide the audio signal from any of the audio input devices 14, 16, 18, 20 across channel one 32 to the channel one control module 24. The channel one control module 24 can communicate the desired audio input device to multiplexer 22 a long line 28. The channel one control module 24 is in communication with a control unit 46, front speakers 48, and a switch 40 along line 36. The control unit 46 allows the front seat passenger to configure the audio system and may be mounted in the instrument panel or integrated into the steering wheel. In the default operating mode, switch 40 connects the channel one control module 24 with the rear speakers 50 across lines 36 and 42. As one skilled in the art can appreciate, the audio system 12, including the multiplexer 22, the switch 40, and channel control modules 24, 26, may be in the form of an embedded system and controlled by software.

Similar to the channel one control module 24, the multiplexer 22 can also provide the audio signal from any of the audio input devices 14, 16, 18, 20 across channel two 34 to the channel two control module 26. For the channel two control module 26, the desired audio input device is communicated to the multiplexer 22 across line 30. The channel two control module 26 is connected to the switch 40 along line 38. Switch 40 includes a dual operating mode that allows the audio system 12 to deactivate the rear speakers 50 and connect the channel two control module 26 with the transceiver 52 along lines 38 and 44. The transceiver 52 is adapted to establish a two way wireless communication link 53 with a transceiver 54 connected to a headphone 56. Tranceivers 52, 54 are implemented using infrared or radio frequency tranceivers, these components are commercially available for example HDSL-1100 from Agilent Technologies of Palo Alto, Calif. In addition, a set of controls 58 are integrated with the headphone 56 for configuring the audio parameters associated with the channel two control module 26 of the audio system 12.

In another aspect of the present invention, a power “on” control 60 will be integrated into the headphone 56. As the power “on” control 60 is activated, the switch 40 will automatically enter the dual operating mode deactivating the rear speakers and connecting the channel two control module 26 to the headphone 56.

A flow chart illustrating the method of controlling the automotive entertainment system 10 according to the present invention is shown in FIG. 2. Block 70 represents the default operating mode where the audio signal from channel one 32 of the audio system 12 is transmitted to the set of front speakers 48 and a set of rear speakers 50.

Decision diamond 72 denotes an event including headphone power “on” or dual-mode control activated. When an event which requires the switch 40 to activate the dual operating mode has not occurred the logic follows path 74 remaining in the default operating mode represented by block 70. When an event has occurred which requires the switch 40 to activate dual operating mode the logic follows path 76 and a control signal is generated by the headphones 56 to initiate the dual operating mode as indicated in block 78. The control signal is transmitted from the headphone 56 to the audio system 12 over the wireless communication link 53 as denoted by box 80. Upon receiving the control signal from the headphone 56 the switch 40 enters the dual operating mode represented by block 82.

In the dual operating mode, the set of rear speakers 50 is deactivated and the audio signal from channel two 34 of the audio system 12 is transmitted to the headphone 56 over the wireless communication link 53. In addition, the audio signal from channel one 32 is still transmitted to the set of front speakers as also denoted in block 82. Decision diamond 84 denotes an event requiring the dual operating mode to be deactivated. When an event requiring the deactivation of the dual operating mode has not occurred, the logic follows path 86 remaining in the dual operating mode represented by block 82. Conversely, when an event requiring deactivation of the dual operating mode has occurred the logic follows path 88 initiating the default operating mode represented by block 70.

As a person skilled in the art will readily appreciate, the above description is meant as an illustration of implementation of the principles this invention. This description is not intended to limit the scope or application of this invention in that the invention is susceptible to modification, variation and change, without departing from spirit of this invention, as defined in the following claims.

1. An automotive multimedia entertainment system for an automotive vehicle having a plurality of audio output devices, the system comprising:
an audio system adapted to communicate with the plurality of audio output devices, the audio system having a first and second output channel;
a headphone including controls, the controls adapted to configure the audio system;
a two way wireless communication link providing audio signals to the headphone and providing a set of control signals to the audio system;
a set of front speakers and a set of rear speakers, said sets of front and rear speakers being in communication with the audio system, the audio system having a switch with first and second modes, in the first mode the switch connecting the set of rear speakers and the headphone to the first output channel, in the second mode the switch deactivating the set of rear speakers and connecting the headphone to the second output channel.

2. The system according to claim 1, wherein the first mode of the switch the controls can configure the first output channel.

3. The system according to claim 1, wherein the second mode of the switch the controls can configure the second output channel.

4. The system according to claim 1, wherein the controls are located on the headphone.

5. The system according to claim 1, wherein the headphone includes a power on control and the headphone is adapted to automatically change the switch of the audio system into the second mode when the power on control is activated.

6. The system according to claim 1, wherein the headphone includes a transceiver.

7. The system according to claim 6, wherein the transceiver is an infrared transceiver.

8. The system according to claim 6, wherein the transceiver is a radio frequency transceiver.

9. The system according to claim 1, further comprising at least one additional headphone including controls adapted to configure the audio system, each additional headphone adapted to communicate the set of control signals over the two-way communication link such that the set of control signals from the headphone are interchangeable with the set of control signals from the at least one additional headphone.

10. An automotive multimedia entertainment system for an automotive vehicle having a plurality of audio output devices, the system comprising:
an audio system adapted to communicate with the plurality of audio output devices, the audio system having a first and second output channel;
a headphone including controls, the controls being adapted to configure the audio system;
a two way wireless communication link for providing audio signals to the headphone and providing a set of control signals to the audio system;
a set of front speakers and a set of rear speakers, the sets of front and rear speakers being in communication with the audio system, the audio system having a switch with first and second modes, in the first mode the switch connecting the set of rear speakers and the headphone to the first output channel, in the second mode the switch deactivating the set of rear speakers and connecting the headphone to the second output channel, wherein the headphone includes a power on control and the headphone is adapted to automatically change the switch of the audio system into the second mode when the power on control is activated.

11. The system according to claim 10, wherein the first mode of the switch controls can configure the first output channel.

12. The system according to claim 10, wherein the second mode of the switch the controls can configure the second output channel.

13. The system according to claim 10, wherein the controls adapted to configure the audio system are located on the headphone.

14. The system according to claim 10, wherein the headphone includes a transceiver.

15. The system according to claim 14, wherein the transceiver is an infrared transceiver.

16. The system according to claim 14, wherein the transceiver is a radio frequency transceiver.

17. The system according to claim 10, further comprising at least one additional headphone including controls adapted to configure the audio system, each additional headphone adapted to communicate the set of control signals over the two-way communication link such that the set of control signals from the headphone are interchangeable with the set of control signals from the at least one additional headphone.

18. A method for controlling an automotive multimedia entertainment system comprising the steps:
transmitting an audio signal from a audio system to a set of front speakers and a set of rear speakers;
transmitting a control signal from a headphone over a wireless communication link to the audio system;
deactivating the rear set of speakers; and
transmitting an audio signal over a wireless communication link to the headphone.

19. The method according to claim 18 wherein the steps of deactivating of the rear set of speakers and transmitting an audio signal to the headphone occur simultaneously.

20. The method according to claim 18, further comprising the step of generating the control signal in response to a control mounted to the headphone.

21. The method according to claim 18, wherein the steps of deactivating the rear set of speakers and transmitting an audio signal to the headphones occur automatically as the headphones are powered on.

22. The method according to claim 18, wherein the wireless communication link is an infrared wireless communication link.

23. The method according to claim 18, wherein the wireless communication link is a radio frequency wireless communication link.
